(19) United States
(12) Patent Application Publication
(10) Pub. No.: US 2021/0126050 A1
(43) Pub. Date: Apr. 29, 2021

(54) ELECTRIC DEVICE WAFER

(71) Applicant: RF360 EUROPE GMBH, Munchen (DE)

(72) Inventors: Veit MEISTER, Unterhaching (DE); Ulrike RÖSLER, Hebertshausen (DE)

(21) Appl. No.: 16/617,396

(22) PCT Filed: Jun. 6, 2018
(86) PCT No.: PCT/EP2018/064877

§ 371 Date: Nov. 26, 2019

(30) Foreign Application Priority Data
Jun. 8, 2017 (DE) 102017112659.7

(51) Int. Cl. H01L 27/20; H01L 27/06; H03H 9/02

(52) U.S. Cl. CPC H01L 27/20; H03H 9/02976; H01L 27/0629

(57) ABSTRACT

A device wafer comprises a silicon substrate, a piezoelectric layer arranged on and bonded to the silicon substrate and a structured metallization on top of the piezoelectric layer. The metallization forms functional device structures providing device functions for a plurality of electric devices that are realized on the device wafer. Semiconductor structures realize a semiconductor element providing a semiconductor function in the semiconductor substrate. Electrically conducting connections providing e.g. ohmic contact between the semiconductor structures and functional device structures such that at least one semiconductor function is controlled by a functional device structure or that at least one device function of the functional device structures is controlled by the semiconductor structures.

The invention refers to an electric device wafer carrying functional structures of electric devices. Especially, the invention refers to electric devices requiring a piezoelectric layer, preferably electric devices that are using acoustic waves like SAW (surface acoustic waves) for example.

Standard systems of such type are manufactured from device wafers having a piezoelectric layer on a low doped, high resistance Si-wafer. Such wafers can easily be manufactured by e.g. wafer bonding a piezoelectric wafer onto a semiconductor wafer. Thinning or cleaving of the bonded piezoelectric layer may follow to result in a piezoelectric layer of a desired thickness.

From published US patent application, US2015/0102705 A1, another elastic surface wave device is known that uses a specific kind of device wafer for advanced operation of an electric device with elastic waves. A layer system is described that uses a mechanically stable carrier substrate on which a layer system comprising the piezoelectric layer is applied.

Manufacture of the device wafer can be done in a “simple” process and no photolithography is required before the wafer bonding step. But a relative thin piezoelectric layer and a low conductivity of the Si-Wafer cause problems with electric isolation and a too high thermal resistance. Electric isolation between different functional device structures is limited. In the case of SAW devices, the functional structures comprise acoustic tracks. Between different acoustic tracks electric isolation may be required and further, a capacitive coupling between different acoustic tracks has to be minimized to avoid worsening of the device performance and cross talk. Further, low doped, high resistance Si-wafers produce higher costs compared to standard substrates on cheap materials.

It is an object of the current invention to provide an electric device wafer that reduces the problems mentioned before. A preferred object is to improve the electric isolation between different device structures like acoustic tracks for example. Another object is to provide an electric device wafer for devices having more functions and/or controllable or switchable properties.

At least one or more of these objects is met by a device wafer according to claim 1. Embodiments that may provide further advantages or improved functions are given by dependent sub-claims.

The device wafer of the invention is a bonded wafer carrying functional device structures for a plurality of electric devices. The respective single electric devices can be received by singulating them from the device wafer.

The device wafer comprises a semiconductor substrate functioning as a carrier for a piezoelectric layer arranged on and bonded to the semiconductor substrate. On top of the piezoelectric layer a structured metallization is arranged forming the functional device structures. Device functions for the plurality of electric devices are provided and enabled by the device structures. The semiconductor substrate may comprise silicon or any other semiconductor like GaAs or another III/V compound. Ge is also a possible semiconductor material for the semiconductor substrate.

In the semiconductor substrate semiconductor structures are present providing a semiconductor function. Between the semiconductor structures and the functional device structures an electrically conducting connection is formed to provide an e.g. ohmic contact there between. In the device wafer, at least one semiconductor function is controlled by a functional device structure. Alternatively, at least one device function of the functional device structures is controlled by the semiconductor structures. However, a diode or transistor may be integrated in the semiconductor substrate without being functionally connected to a functional device structure. For example, a buried transistor that may function as an amplifier or a diode functioning as a switch are possible. Such integrated semiconductor elements take profit from the possible short electrical connections and thus reduced parasitic elements.

The device wafer comprises piezoelectric functional devices that are realized at least by the functional device structures and the adjacent piezoelectric layer. Contrary to known devices wherein a semiconductor substrate is usually used as a carrier only, the invention proposes to integrate a semiconductor function into the semiconductor substrate. Further, the device wafer, respectively each functional device of the device wafer, is adapted so that an interaction between the semiconductor elements and the functional device structures is enabled such that one of the semiconductor elements or functional devices is controlled by the respective other element. Such an arrangement has an improved degree of integration and thus helps to reduce size, volume and costs of the device wafer compared to a device wafer according to the art. The high integration of the device wafer further reduces the distances between the different elements to be connected with each other or to interact with each other. Thereby all electric device functions of the functional device and the semiconductor element are accelerated.

Using a bonded wafer like the present device wafer has the further advantage that interaction between device function and semiconductor function is improved.

Interaction between device function and semiconductor function is made by direct (ohmic) contact or by an indirect coupling that may be controlled by an electric field or a capacitive coupling. In both cases, the short distance between both structures is advantageous for the function of the device.

According to an embodiment the semiconductor structures are realizing a switch. Such a switch may be manufactured by any semiconductor technique that can be realized within the semiconductor substrate. The switch may be realized as a diode, a bipolar transistor or a field-effect transistor FET.

The shortest distance between semiconductor structures and device structures, and hence an optimized interaction between both, is achieved if semiconductor structures and device structures are facing each other at least partly on both sides of the piezoelectric. The shorter the distance between different structures, the better the interaction thereof.

According to one embodiment the semiconductor structures are enabled to control a charge in a chargeable surface region of the semiconductor substrate. The chargeable surface region forms a capacitance with a functional device structure. Such a chargeable surface region needs a doping within the semiconductor substrate and a barrier that prevents charge carriers from leaving the doped zone. To do so, the chargeable surface region may be embedded in a doped well that forms a pn junction between the chargeable surface region and the surrounding semiconductor material of the semiconductor substrate. The pn junction works as a barrier confining and restricting the charge carriers within the chargeable surface region. To control the charge in the chargeable surface region a conducting channel is necessary to charge or decharge the chargeable surface region through the channel. The conducting channel may be opened or closed by the switch and hence by a semiconductor function. The amount of charges within the charged surface region can be controlled by a given potential difference and/or the work function of semiconductor and electrode material. Further it is possible to set or control the required potential by trapped ions that are implanted into the surface of the semiconductor or at any interface to a dielectric layer.

The semiconductor substrate of the device wafer may be of a high quality and a low conductivity that is of a high purity. Such a material allows to integrate therein any desired semiconductor function that is realizable in the semiconductor.

According to a further embodiment the semiconductor substrate comprises a carrier wafer of a doped silicon material and a high-ohmic epitaxial silicon layer that is grown on top of the carrier wafer and has a type of conductivity inverse to that of the carrier wafer. The semiconductor structures and semiconductor elements are completely realized within the epitaxial silicon layer. This embodiment has the advantage that a silicon material of low impurity and hence high quality is only necessary for the epitaxial layer. As the epitaxial layer does not need to have a thickness high enough to function as a carrier, a thin epitaxial layer is sufficient. This helps minimizing the high costs of the high quality material as the doped silicon material of the carrier wafer is of a lower quality and hence by far less expensive than the high quality silicon of the epitaxial layer.

A further advantage of this embodiment is achieved by a pn junction that forms between the inverse doped epitaxial layer and the silicon material of the carrier wafer.

In a preferred embodiment the carrier wafer is doped to provide an n+ conductivity while the epitaxial layer is doped to provide a p− conductivity. The semiconductor structures can then be manufactured by introducing further dopants in a surface region of the epitaxial layer. These dopants may form other semiconductor junctions to provide an active semiconductor element or electrically conducting or chargeable zones.

The device wafer comprises functional device structures and semiconductor structures for a plurality of electric devices where each device may comprise one or more of these functional device structures and/or semiconductor structures. If a plurality of semiconductor structures that may realize different semiconductor functions are present, it may be necessary to electrically isolate these different semiconductor structures. According to an embodiment a first and a second semiconductor element, each comprising semiconductor structures, are arranged in a surface region of the epitaxial layer. First and second semiconductor elements are isolated against each other by an isolating barrier formed as isolating bar between the two semiconductor elements or as an isolating frame surrounding and enclosing one or both of first and second semiconductor element.

The barrier extends from the top surface of the semiconductor substrate down to a depth that is sufficient for isolation. A sufficient depth is at least a depth of the bottommost semiconductor structure of the respective semiconductor element.

The barrier may be embodied in two different ways. It may comprise a dielectric material that is buried within the surface of the semiconductor substrate. Alternatively the barrier can be embodied as a zone that is doped inversely with regard to the high ohmic epitaxial silicon layer the zone is embedded in. Hence, in the first case the dielectric material forms an ohmic barrier while in the second case the doped zone provides a pn junction and hence a barrier formed by a depletion zone at the interface.

According to a further embodiment the device wafer is enabled to apply a BIAS voltage between functional device structures and the bulk material of the semiconductor substrate. The bulk material of the semiconductor substrate may be contacted by a buried conductor. Alternatively, the bulk material may be contacted by a backside metallization on the bottom surface of the semiconductor substrate.

When applying a BIAS voltage across a doped semiconductor material a space charge region forms at the isolating barrier that is provided by the isolating piezoelectric material. As a consequence, charges enrich in a zone directly adjacent to the interface between semiconductor substrate and piezoelectric layer. The amount of charges is dependent on the degree of doping at the interface and value of the BIAS voltage applied. The charge carriers in the space charge region can be used as an electric potential that forms a capacitance to the other metallic functional device structures the BIAS voltage is applied to. This capacitance can be used for the function of a semiconductor element or, more advantageously, to directly control the function of the functional device.

The buried contact for the capacitance can be formed by any method and is preferably a high doped zone. But any ohmic conducting material may be possible too. Hence it is possible to bury a metallic line or area as a buried contact.

If the BIAS voltage is applied to a backside metallization, this metallization needs to be structured and restricted to an area where the BIAS voltage is required. By structuring, one or more electrically isolated areas can be achieved, each area being adapted so that a BIAS voltage can be applied thereto. By this, different space charge areas of different potentials dependent on the applied BIAS voltage are possible.

According to another embodiment a first BIAS voltage is applied across the semiconductor substrate at a first functional device structure and a second BIAS voltage is applied across the semiconductor substrate at a second functional device structure. First and second BIAS voltage are different such that capacitive elements of different capacitance are formed.

In so far as the above explanation refers to the whole device wafer, the same is true for the functional devices of single devices that are realized in parallel on the device wafer. This means, if a device wafer provides a number of n devices arranged thereon at least n functional structures for these n devices are present on the device wafer.

The same is true for the semiconductor elements realized by semiconductor structures. The number of these semiconductor elements complies with the number of devices present on the device wafer. If a single device comprises more than one functional structure and more than one semiconductor structure, the number thereof has to be multiplied accordingly.

Starting from the device wafer single electric devices can be singulated therefrom by a method of separation. A preferred separation method comprises a sawing process. But any other cleavage, for example laser cutting or similar methods are possible too. The single electric device may be a SAW device, a BAW device or a piezoelectric sensor element. With the help of the integrated semiconductor elements it is possible to integrate sophisticated functions within these devices. The devices may be tuned, switched or otherwise controlled by the semiconductor elements.

According to an embodiment an electric device comprises functional device structures that realize an acoustic resonator in or on the piezoelectric layer. The resonator has a static capacitance as usual. Further, a semiconductor element is present that is enabled to control a charge in a chargeable surface region of the semiconductor substrate. The so-charged surface region forms a capacitance with a functional device structure such that the capacitance adds to the static capacitance of the device to be part thereof. By the controlled charge in the chargeable surface region the resonator can be tuned in its resonance frequency as the resonance frequency is dependent on the static capacitance and the static capacitance can be controlled by the charge in the chargeable surface region.

A semiconductor element that is able to control a charge in a chargeable surface region has been explained above and may comprise a diode, an FET (field-effect transistor) or a bipolar transistor. Instead of a transistor switch having a gate electrode (voltage controlled) also an optical transistor may be used. Such a transistor is governed by a light source which can induce carriers between a first and a second electrode applied on top of the semiconductor substrate. By the charge carriers induced by impacting light a conducting channel forms on the top surface of the semiconductor substrate.

According to a further embodiment such an optical controlled transistor may be provided with an optical filter that can let only a limited range of wavelengths pass. When using different optical filters with different passing frequencies it is possible to activate a desired optical transistor by using an according wavelength for activating or switching the respective transistor.

In the following the invention will be explained in more detail by reference to specific embodiments and the accompanying figures. The figures are schematic only and not drawn to scale. Therefore, no real dimension or ratio of dimension can be taken from the figures.

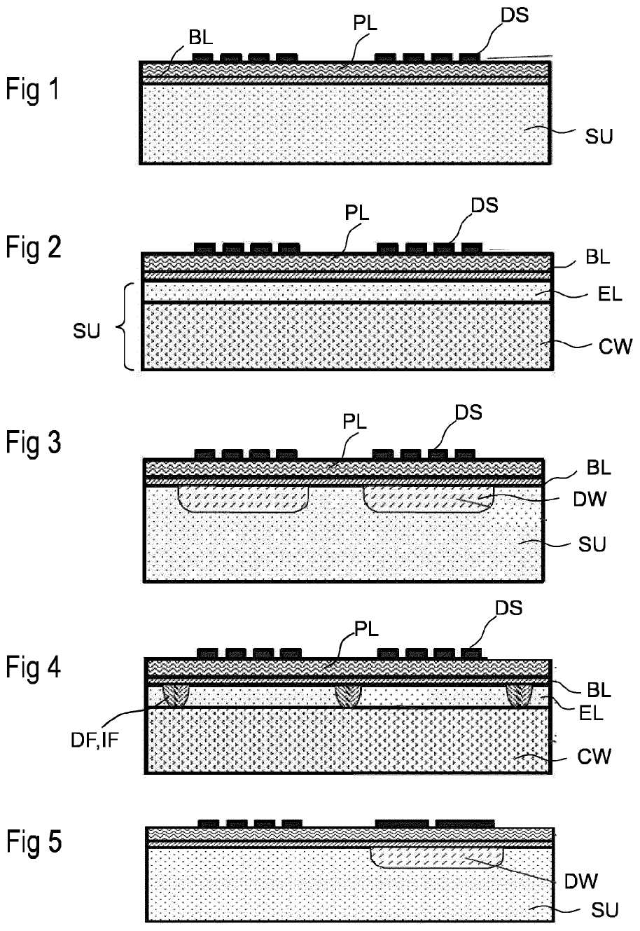

FIG. 1 shows a cross-sectional view through part of a device wafer according to the art;

FIG. 2 shows a device wafer with an epitaxial layer according to an embodiment of the invention;

FIG. 3 shows a device wafer with doped wells according to another embodiment;

FIG. 4 shows a device wafer of another embodiment comprising an epitaxial layer with an isolating barrier arranged in this layer;

FIG. 5 shows a cross-sectional view through a device wafer with adjacent functional device structure for a SAW device and a BAW device as well;

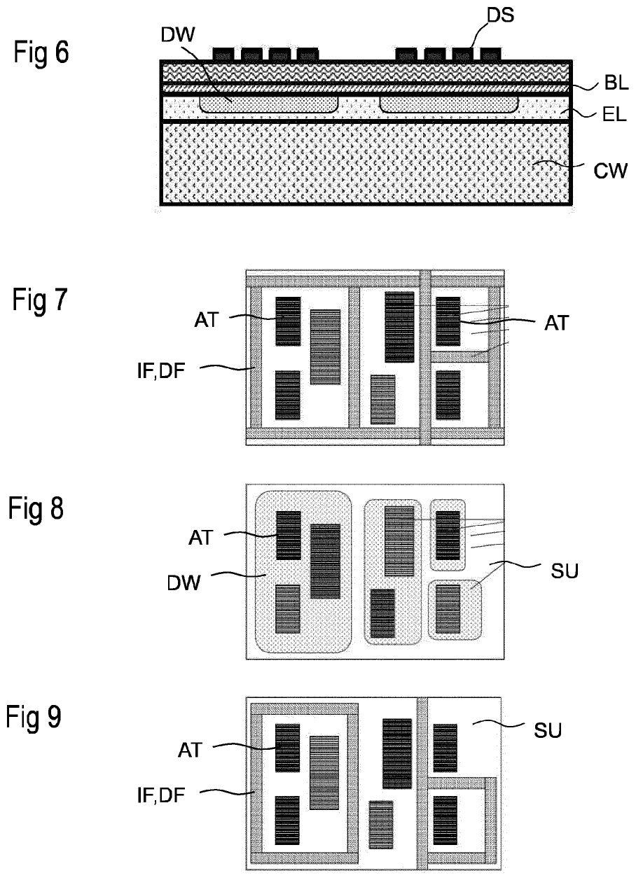

FIG. 6 shows a device wafer with an epitaxial layer including doped wells therein;

FIG. 7 shows, in a top view, device structures of a device wafer that are enclosed by a barrier formed by an isolating material or doped frame-like zone;

FIG. 8 shows, in a top view, the arrangement of device structures within doped wells;

FIG. 9 shows, in a top view, a relative arrangement of a frame and device structures;

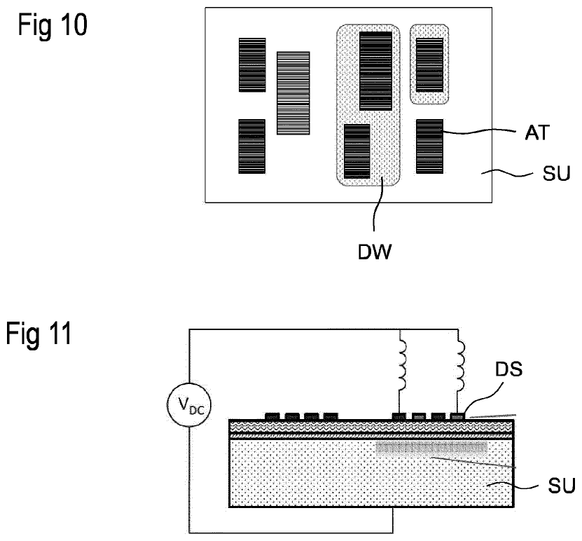

FIG. 10 shows, in a top view, a device wafer where only part of the device structures are arranged within a doped well;

FIG. 11 shows a cross-sectional view through a device wafer comprising means for applying a BIAS voltage between the device structures and the bulk material of the substrate;

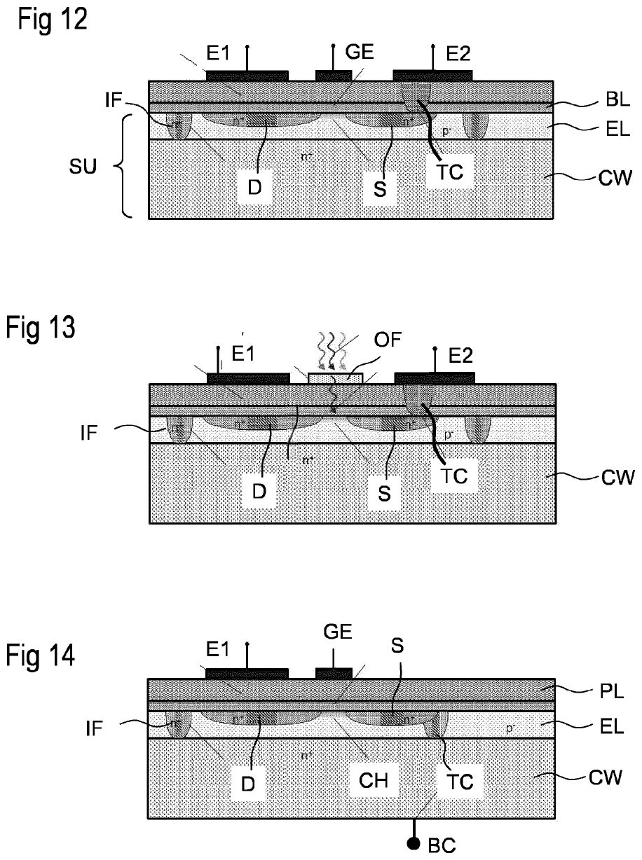

FIG. 12 shows a cross-sectional view through a device wafer with an integrated capacitor that is switchable by a FET transistor realized in a silicon layer of the carrier wafer;

FIG. 13 shows a cross-sectional view through similar device wafer with an integrated capacitor that is controlled by an optically switchable transistor;

FIG. 14 shows a cross-sectional view through another device wafer with a switch and a switchable integrated capacitor;

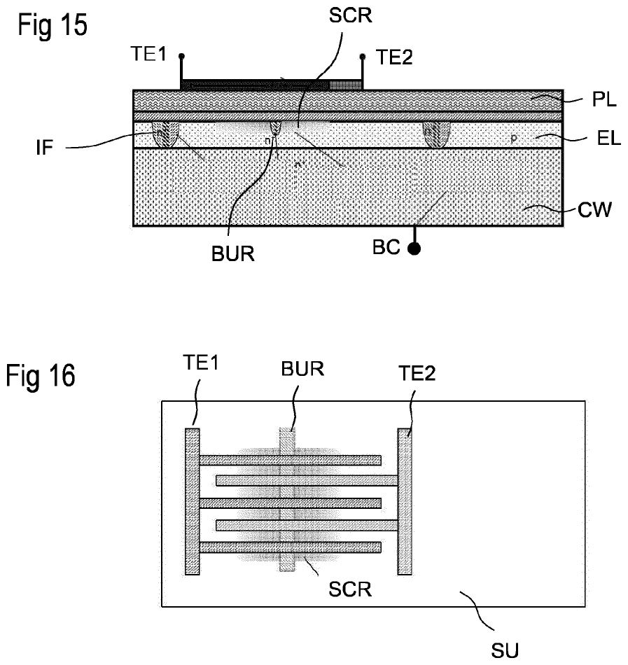

FIG. 15 shows a cross-sectional view through a device wafer with functional device structures of a SAW device facing a space charge region in a silicon layer of the carrier wafer;

FIG. 16 shows the device wafer of FIG: 16 in a top view.

FIG. 1 shows, in a schematic cross-section, a device wafer according to the art. The device wafer comprises a carrier wafer comprising a silicon substrate SU on top of which a layer system is arranged. Such a layer system may comprise a bonding layer BL and a piezoelectric layer PL. The bonding layer may be produced directly on the silicon substrate SU and usually comprises aluminium nitride and/or silicon oxide.

Before or during applying the bonding layer measures for reducing surface charges of the silicon substrate can be made. These measures can comprise a physical treatment of the silicon substrate that is used as a carrier, or applying an additional layer for discharging the surface of the silicon substrate. Such measures are known from the art and need not be explained in more detail.

A piezoelectric layer PL is wafer-bonded on top of the bonding layer BL. The piezoelectric layer PL may be a thick wafer that is wafer-bonded to the substrate and then reduced in thickness by a grinding process or by a wafer cleavage followed by a polishing process. On top of the piezoelectric layer PL metallic device structures DS may be applied. As shown in FIG. 1, the device structures may comprise interdigital transducer electrodes of a SAW device like a SAW filter, for example.

A disadvantage of the shown device wafer is insufficient electric isolation between different device structures DS. The device structures DS to be isolated against each other are interfering with each other by capacitive coupling via charge carriers within the substrate SU. To minimize such coupling, a very low doped silicon substrate SU is necessary. As the low doped silicon material is a very clean material with a very low amount of impurities, this material is expensive.

FIG. 2 shows, in a cross-sectional view, a device wafer according to a first embodiment of the invention. In contrast to the known device wafer according to FIG. 1, the device wafer comprises a silicon substrate SU that is weakly or high doped and provides a certain amount of conductivity. On top of the silicon substrate SU a high-ohmic epitaxial layer EL is applied. Any epitaxial silicon deposition may be used to manufacture this epitaxial layer.

Silicon substrate SU and high-ohmic epitaxial layer EL may comprise dopants providing the same type of conductivity. This embodiment provides improved thermal conductivity by the doped bulk silicon substrate in view of a high purity silicon wafer. Nonetheless and in cause of the high-ohmic epitaxial layer there is the possibility to integrate semiconductor elements or simply pn junctions in the epitaxial layer.

However, to provide a space charge region between epitaxial layer EL and silicon substrate SU, different doping is used for both layers. For example, the silicon substrate SU may have a n+ doping. The epitaxial layer may then be low conductive and, for example p− doped.

The piezoelectric layer PL may be a lithium tantalate layer, for example. But any other piezoelectric material is useful for the invention. The piezoelectric layer may have a relatively low thickness of about two times the acoustic wavelength the device is working with. Thicker piezoelectric layers of e.g. fpm thickness working at a frequency between 800 MHz and 2.6 GHz are possible too. The epitaxial layer thickness may be in the same order. But a higher or lower thickness or may be possible too. In the course of the pn junction between epitaxial layer EL and silicon substrate SU a space charge region forms that isolates the two layers against each other by forming a respective barrier.

FIG. 3 shows a schematic cross-section of further embodiment. In this example a very low doped silicon substrate SU is used, for example, an n− doped silicon. Near the surface and directly under a group of device structures DS a doped well DW is formed by implanting therein a dopant that provides a conductivity of the contrary type. In the example the doped wells comprise a p− doping. With these doped wells a pn junction is formed at the interface of the doped well and the silicon substrate. A space charge region forms and provides a barrier that prevents charge carriers to leave the doped well. Hence, the doped well provides a perfect isolation of the region opposite to the device structures such that device structures that have to be isolated against each other are arranged opposite to separate and different doped wells DW.

FIG. 4 shows in a cross-sectional view the method to further improve the isolation between different device structures DS that may be present in a device wafer as shown in FIG. 2. In addition to the pn junction between epitaxial layer EL and silicon substrate SU an isolating frame IF is formed as a barrier within the epitaxial layer EL. The isolating frame IF extends from the top surface of the epitaxial layer EL to the top surface of the silicon substrate SU. It may be manufactured by forming a trench, for example by etching, and then filling up the trench with an isolating material like silicon oxide for example. Any other dielectric may be possible too.

The filling of the trenches may be accomplished by applying an isolating dielectric to the entire surface of the epitaxial layer before forming the bonding layer BL. The isolating layer is applied in a thickness that is sufficient to totally fill the trenches. Then the surface may be planarized by grinding or back-etching such that a plane surface remains. Alternatively the trench can remain unfilled to provide an air-filled isolating trench. In this case, it may be advantageous to form the trench during manufacturing of the carrier wafer as a last step before bonding the piezoelectric wafer to the carrier wafer.

The isolating frame IF surrounds a surface region that faces device structures DS to be isolated against other device structures. The same isolating material filling the trench may be used in parallel to form a bonding layer BL for improving the bonding strength between carrier wafer and piezoelectric layer.

Alternatively, a bonding layer BL is applied separately on top of the carrier wafer in a usually known manner. Then the piezo layer PL is applied on top of the bonding layer BL and device structures DS are formed on top of the piezoelectric layer. In this embodiment the surface region of the epitaxial layer EL opposite to a group of device structure DL is isolated against the silicon substrate SU by the pn junction between epitaxial layer and silicon substrate. In case the surface region is embedded in a doped well a further pn junction at the periphery of the doped well provides further improved isolation. In any case, adjacent types of device structures DS are isolated against each other by the isolating frame IF.

In a variant also depicted in FIG. 4 the barrier DF comprises a doped zone DF that may be formed frame-like. Alternatively, the barrier may extend linearly between two surface regions of the substrate to be isolated against each other.

The dopant used in the doped zone DF is of contrary type to the dopant used in the remaining epitaxial layer EL such that a pn junction is formed between the low doped epitaxial layer EL and the doped frame-like zone DF. In this example, the doped zone DF may be n⁺ doped. The doping may comprise applying a doping mask on top of the epitaxial layer EL before diffusing in or implanting the dopant and before applying the bonding layer BL. In the doping mask only those regions are exposed where the doped zone DF is to be produced.

In a further embodiment according to FIG. 5 device structures forming two different types of devices are present on top of the piezoelectric layer PL. First device structures DS1 realize a SAW device schematically depicted as a cross-section through an interdigital transducer. Second device structures DS2 realize two top electrodes of a two series-connected BAW devices that may be arranged directly adjacent to the SAW device. The common counter electrode of the two series BAW resonators is not a metal electrode but a doped well DW within the silicon substrate or within the epitaxial layer (not shown in the figure) opposite to the second device structures DS2. The doped well may be n⁺ doped while the substrate is p⁻ doped. Alternatively the epitaxial layer is p⁻ doped while the silicon substrate is n⁻ doped.

In an embodiment according to FIG. 6 an isolation inverse to the embodiment shown in FIG. 4 is used. While the embodiment of FIG. 5 uses doped zones as a barrier between surface regions, FIG. 6 provides doped wells formed in a surface region within the epitaxial layer EL. This is similar to the embodiment of FIG. 3 with the advantage that the weakly doped and low conductive epitaxial layer EL has only a small thickness over a silicon substrate SU that may be strongly doped. Besides the pn junction between epitaxial layer EL and silicon substrate SU, a further pn junction is formed between the doped wells and the remaining area of the epitaxial layer outside and surrounding the doped wells DW.

While in the embodiment of FIG. 4 a frame-like zone DF is doped and the epitaxial layer remains un-doped, FIG. 6 provides an embodiment where the region opposite to the device structures is conductive and the remaining epitaxial layer is low conductive.

FIG. 7 shows in a top view onto a device wafer how different device structures DS can be isolated against each other. As a device structure DS, acoustic tracks AT of a SAW device are formed. By a barrier like isolating frames IF or doped zones DF different areas of the carrier wafer may be isolated against each other. Each isolated area may comprise one or more device structures like acoustic tracks AT as shown in the embodiment. While the area shown on the left side of the figure comprises three acoustic tracks AT surrounded by an isolating frame IF or a doped zone DF, the area shown in the middle of the figure comprises two acoustic tracks AT within one enclosing barrier and in the area shown on the right side of the figure only one acoustic track each is surrounded by a respective isolating frame IF or frame-like doped zone DF.

The isolating frames are formed and arranged between device structures DS that have to be isolated against each other.

These may be for example between interdigital transducer electrodes of an input transducer and an output transducer. It is also possible to use this kind of isolation to separate parts within a track from each other, e.g. in DMS structures (IN vs. OUT), to isolate parts of MPR filters (multi-port resonator) or to separate parts of cascaded resonators (e.g. frame/trench below “bus-bar” between tracks of a cascade).

FIG. 8 is a top view onto a device wafer according to the embodiment shown in FIG. 3 or FIG. 6. The figure shows how the doped wells DW may be arranged within the surface of the silicon substrate SU or the epitaxial layer EL. Similar to the embodiment of FIG. 7, several device structures like acoustic tracks AT may be arranged within one doped well DW. Different doped wells DW may comprise a different number of device structures as shown. Accordingly, the doped wells may comprise different surface areas.

FIG. 9 shows another arrangement of isolating frames IF or doped frame-like zones DF in a top view on a device wafer according to the invention. On the left side, a frame surrounds and isolates a number of device structures like acoustic tracks AT. Two other acoustic tracks shown in the middle of the figure do not need to be surrounded by a frame, but are isolated against the acoustic tracks on the right part of the figure by a non-surrounding barrier zone that is formed linearly as a bar like barrier to isolate the not-surrounded device structures against the surrounded and non-surrounded device structures on the right side. As shown in FIG. 9, barriers formed as surrounding frames and linearly extending isolating zones may be present on the same device wafer. But it is also possible that only linearly extending isolating zones are necessary to isolate different regions on top of the silicon substrate, each region being opposite to one or more device structures that need to be isolated against other device structures.

FIG. 10 shows another possibility to arrange doped wells DW in a silicon substrate SU or an epitaxial layer EL according to the embodiments shown in FIGS. 3 and 6. In FIG. 10 two doped wells DW comprise at least one device structure that is at least one acoustic track AT. Other acoustic tracks AT are arranged outside the doped wells DW. In spite of not being arranged in the doped well, the device structures or acoustic tracks AT shown in the left part of FIG. 10 are isolated against the device structures arranged in a doped well by virtue of the pn junction between the doped well and the remaining un-doped area outside the doped well DW.

FIG. 11 shows a cross-section of a device wafer according to another embodiment. A space charge region is formed as a depletion region due to an applied DC BIAS voltage VDC. The BIAS voltage is applied between device structures DS and the bulk material of the silicon substrate SU, for example by applying a metallized area on the bottom surface of the silicon substrate SU. Because of the BIAS voltage, charge carriers enrich in a zone EZ opposite to the device structures DS the BIAS voltage is applied to. As a result, enhanced conductivity in the enriched zone EZ opposite to the device structures DS is achieved and a capacitance CAP forms between the device structures DS and the enriched region opposite thereof in the upper surface of the silicon substrate. This capacitance may add to the static capacitance of the device the device structures belong to. By varying the capacitance of the device, properties thereof may be changed. As a consequence of an enhanced static capacitance of an interdigital transducer electrode, the resonance frequency thereof may be tuned. But every other property that is dependent on a capacity may be tuned by such a DC BIAS voltage too.

Applying an inverse bias voltage may lead to a depleted zone below the device structure reducing the capacitance in this region and thus, resulting in the same effect of tuning resonance frequency.

FIG. 12 shows a cross-sectional view through a device wafer with a capacitor integrated within the epitaxial layer EL. The capacitor is switchable by a FET transistor that is also realized in the epitaxial silicon layer of the carrier wafer. Electrodes of the FET transistor for source E2, drain E1 and gate GE are formed by the structured metallization on top of the piezoelectric layer PL functioning as an isolating layer. The capacitor electrodes are formed by the drain terminal E1 and the drain region D below E1. As the drain region has no electrical connection it is a floating electrode the potential thereof being controlled by the transistor's gate electrode GE. However, source and drain may be interchanged that the capacitor is formed by the source electrode E2 and the source S itself. Transistor and capacitor are series circuited.

A bonding layer may be present at the interface between piezoelectric layer PL and epitaxial silicon layer EL that is isolating too. Hence, the electrode E2 for the source needs an ohmic contact through the isolating layer. This contact can be formed by a via, a through contact TC or any other conducting structure. Source S and drain D itself are highly doped zones in the epitaxial layer EL directly facing the respective electrodes E1 and E2. The highly doped zones may be n⁺ doped wells in the p⁻ doped epitaxial layer EL. The drain electrode El is not in direct electrical contact with the drain D. Hence, a capacitor forms between electrode E1 and drain as soon as the transistor works and charges the drain D with charge carriers. Loading of the drain is enabled by applying a positive potential to the gate electrode for forming an n-conducting channel CH under the gate electrode GE.

The drain electrode E1 may be a part of the functional device structures DS of the device wafer. Then, the capacitance that is switchable by the transistor can co-operate with the device for example by adding to the static capacitance of the functional device e.g. a SAW resonator.

In the figure, the transistor is isolated by a frame-like barrier IF as shown in FIGS. 4, 7 and 9 surrounding source S, drain D and channel CH of the transistor.

FIG. 13 shows a cross-sectional view through similar device wafer having an integrated capacitor switchable by a FET transistor. Instead of applying a voltage to a gate electrode like at the transistor of FIG. 12 the conducting channel CH of FIG. 13 can be enabled by light. Absorbance of light in the region of the channel CH between source S and drain D within the epitaxial layer EL induces charge carriers, forms a conducting channel CH and allows to charge the drain D if a voltage is applied over the electrodes E1 and E2 for source and drain.

An optional optical filter OF enables the transistor to be switched by light of a selected wavelength that may pass the optical filter OF. Using different optical filters OF with a different passband frequency each allows to selectively switch a desired transistor by selecting a respective wavelength of light that can pass the respective optical filter OF.

In FIG. 13 the optical filter is embodied as a layer on top of the piezoelectric layer PL. Alternatively, the optical filter OF as well as the electrodes of the transistor may be buried at a desired depth within the device wafer. These buried contacts may be in contact with no, one or more than one electrode on the top side by vias TC.

FIG. 14 shows a cross-sectional view through another device wafer with a switch formed by an integrated FET transistor and a switchable integrated capacitor. Instead of a via to the top side the drain region D may be contacted by via or any other contact means to the bulk material of the silicon substrate SU. Hence, the silicon needs to be provided with a backside or bulk contact BC. It may be advantageous to place the bulk contact BC opposite to the transistor zone to be contacted.

FIG. 15 shows a cross-sectional view of a device wafer with functional device structures DS of a SAW device facing a space charge region SCR in a silicon layer of the carrier wafer. The space charge region forms when a DC BIAS voltage is applied between device structures DS and a bulk contact BNC at the bottom side of the silicon substrate SU as already shown and explained with reference to FIG. 11. As a further advantageous feature the space charge may be modulated by a buried contact BUR within the space charge region that is at or near the top surface of the epitaxial silicon layer EL.

The dimension of the space charge region SCR depends on the BIAS voltage between device structures DS and bulk contact BC. The buried contact may be a floating contact or may be in electrical contact the bulk contact or any metal contact at the top surface of the piezoelectric layer. The space charge region SCR and device structures DS form a capacitance for modifying a property of the functional device.

Alternatively, the space charge region may be formed by means of light the top surface is irradiated with. As explained before a wavelength that is absorbed in the epitaxial layer is chosen. Using a radiation of higher energy is possible too.

FIG. 16 shows the device wafer of FIG. 16 in a top view. The device is a SAW device and the depicted device structure DS is a SAW transducer which may be part of a SAW resonator. The space charge region SCR is located under the transducer that a capacitance there between can form.

As the depicted transducer comprises two electrodes TE1, TE2 electrically isolated against each other, the BIAS voltage may be applied to one of the two electrodes or to both electrodes. The capacitance that forms between electrode and space charge region SCR has only minor dependence onto whether one or two electrodes are biased.

The invention has been explained and depicted with reference to a limited number of embodiments and figures. However the scope of the invention and is hence not restricted to the embodiments. As in most figures only one a single aspect of the invention is shown, it is within the scope of the invention to combine different features shown in different figures. Hence, it is possible to combine a doped well and an isolating or a doped frame. Further, each lateral structuring may be done within an epitaxial layer or within the silicon substrate alternatively or additionally. But in each most cases photolithography, epitaxial deposition or doping processes or combinations of them needed before wafer bonding. Other manufacturing steps of structuring and/or doping the carrier wafer may alternatively be done after wafer bonding. E.g. ion implanting can be done through any barrier layer or other layer to form structures at a depth within the wafer that is depended on the implanting energy e.g. the ion accelerating field. Another step may use the transparency of the piezoelectric layer for a range of wavelengths such that a laser can be used to specifically form a structure that is buried under a covering layer. These buried structures can comprise isolating trenches or any other discontinuity within the carrier wafer.

### LIST OF REFERENCE SYMBOLS

AT acoustic track
BC bulk contact
BUR buried contact
CAP capacitance
CH channel
CW carrier wafer
D drain
DF barrier comprising a dielectric material
DS functional device structures
DW doped zone
E1, E2 transistor electrode
EL high-ohmic epitaxial silicon layer
GE gate electrode
IF isolating frame
OF optical filter
PL piezoelectric layer
S source
SCR space charge region
SR surface region
SU silicon substrate
TC through contact, via
TE transducer electrode

1. A device wafer with functional device structures for a plurality of electric devices, comprising
a semiconductor substrate (SU)
a piezoelectric layer arranged on and bonded to the semiconductor substrate
on top of the piezoelectric layer, a structured metallization forming the functional device structures providing device functions for the plurality of electric devices
semiconductor structures (realizing a semiconductor element and) providing a semiconductor function in the semiconductor substrate, and
electrically conducting connections for providing contact between semiconductor structures and functional device structures
wherein at least one semiconductor function is controlled by a functional device structure, or
wherein at least one device function of the functional device structures is controlled by the semiconductor structures.

2. The wafer of claim 1,
wherein the semiconductor structures are realizing a switch.

3. The wafer of claim 1,
wherein the device structures and the semiconductor structures are arranged facing each other at least partly (on both sides of the piezoelectric layer) to enable an contactless interaction thereof by capacitive coupling or by an electrical field.

4. The wafer of claim 1,
wherein the semiconductor structures are enabled to control a charge in a chargeable surface region of the semiconductor substrate, the chargeable surface region forming a capacitance with a functional device structure.

5. The wafer of claim 1,
wherein the semiconductor structures are realizing at least one semiconductor element chosen from diode, bipolar transistor and FET.

6. The wafer of claim 1,
wherein the semiconductor substrate (SU) comprises
a carrier wafer (CW) of a doped silicon material, and
a high-ohmic epitaxial silicon layer (EL) grown on top of the carrier wafer and having a type of conductivity inverse to that of the carrier wafer wherein the semiconductor structures and elements are realized within the epitaxial silicon layer.

7. The wafer of claim 1,
wherein a first and a second semiconductor element are arranged in a surface region wherein first and second semiconductor element are isolated against each other by an isolating barrier formed as isolating bar between the two semiconductor elements or as isolating frame surrounding and enclosing one both of first and second semiconductor element
wherein the barrier extends from the top surface of the silicon substrate into substrate down to a depth that is at least the depth of the bottom of the semiconductor structures
wherein the barrier comprises a dielectric material buried under the surface of the substrate or a zone that is doped inversely with regard to the high ohmic epitaxial silicon layer the zone is embedded in.

8. The wafer of claim 1,
enabled to apply a BIAS voltage between functional device structures and the bulk material of the substrate.

9. The wafer of the foregoing claim 8,
wherein a first BIAS voltage is applied to a first functional device structure and a second BIAS voltage is applied to second functional device structure wherein first and second BIAS voltage are different such that capacitive elements of different capacitance are formed.

10. An Electric electric device with functional device structures, comprising:
a semiconductor substrate (SU)
a piezoelectric layer arranged on and bonded to the semiconductor substrate
on top of the piezoelectric layer, a structured metallization forming the functional device structures providing device functions for the plurality of electric devices
semiconductor structures (realizing a semiconductor element and) providing a semiconductor function in the semiconductor substrate; and
electrically conducting connections for providing contact between semiconductor structures and functional device structures;
wherein at least one semiconductor function is controlled by a functional device structure, or at least one device function of the functional device structures is controlled by the semiconductor structures, and
wherein the functional device structures enable operation as a SAW device, a BAW device or a piezoelectric sensor element.

11. The electric device of claim 10, comprising
a functional device structure realizing an acoustic resonator in or on the piezoelectric layer, the resonator having a static capacitance,
a semiconductor element that is enabled to control a charge in a chargeable surface region of the silicon substrate to form a capacitance with a functional device structure the capacitance adding to the static capacitance
wherein the resonator is enabled to be tuned in its resonance frequency by controlling the capacitance.
